(19) United States
(12) Patent Application Publication
(10) Pub. No.: US 2023/0187316 A1
(43) Pub. Date: Jun. 15, 2023

(54) SEMICONDUCTOR STRUCTURE AND METHOD FOR MANUFACTURING SEMICONDUCTOR STRUCTURE

(71) Applicant: CHANGXIN MEMORY TECHNOLOGIES, INC., Hefei City (CN)

(72) Inventor: CHIH-WEI CHANG, Hefei (CN)

(21) Appl. No.: 17/854,181

(22) Filed: Jun. 30, 2022

Related U.S. Application Data
(63) Continuation of application No. PCT/CN2022/076160, filed on Feb. 14, 2022.

(30) Foreign Application Priority Data
Dec. 15, 2021 (CN) 202111537812.6

(51) Int. Cl. H01L 23/48; H01L 21/768; H01L 23/00

(52) U.S. Cl. CPC H01L 23/481; H01L 21/76898; H01L 21/76877; H01L 24/13; H01L 24/05; H01L 2224/131; H01L 2224/13025; H01L 2224/0557

(57) ABSTRACT

A semiconductor structure and a method for manufacturing a semiconductor structure are provided. The method includes: a base is provided, in which the base includes top layer silicon and bottom layer silicon; a device layer is formed on the top layer silicon of the base; a through via penetrating through the device layer and the top layer silicon and extending into the bottom layer silicon is formed; the through via is filled to form a conductive pillar; and preprocessing is performed on the bottom layer silicon of the base to expose the conductive pillar to form a Through Silicon Via (TSV), in which the bottom layer silicon is configured to block a metal contaminant generated in the preprocessing.

### CROSS-REFERENCE TO RELATED APPLICATIONS

The disclosure is a continuation application of International Patent Application No. PCT/CN2022/076160, filed on Feb. 14, 2022, which claims priority to Chinese Patent Application No. 202111537812.6, entitled “SEMICONDUCTOR STRUCTURE AND METHOD FOR MANUFACTURING SEMICONDUCTOR STRUCTURE” and filed on Dec. 15, 2021. The disclosures of International Patent Application No. PCT/CN2022/076160 and Chinese Patent Application No. 202111537812.6 are hereby incorporated by reference in their entireties.

### BACKGROUND

A Through Silicon Via (TSV) is a conductor structure penetrating through a silicon substrate material and is mainly configured to interconnect integrated circuit chips with each other. A current method for forming a TSV mainly includes the following operations. A through via perpendicular to a silicon substrate is formed on a first surface of the silicon substrate. An insulating layer is formed on a side wall and a bottom of the through via. The through via is filled with a conductive material. Chemical Mechanical Polishing (CMP) is performed on a second surface of the silicon substrate opposite to the first surface until the through via filled with the conductive material is exposed, that is, a TSV is formed.

Therefore, how to improve a Backside Via Reveal (BVR) technology for TSVs is an urgent problem to be solved at present.

### SUMMARY

Embodiments of the disclosure relates to the field of semiconductor manufacturing technologies, and in particular, to a semiconductor structure and a method for manufacturing a semiconductor structure.

In view of this, embodiments of the disclosure provide a semiconductor structure and a method for manufacturing a semiconductor structure to resolve at least one of the technical problems in the prior art.

To achieve the foregoing objective, the technical solution of the disclosure is implemented as follows.

According to a first aspect, the embodiments of the disclosure provide a method for manufacturing a semiconductor structure, including the following operations.

A base is provided, in which the base includes top layer silicon and bottom layer silicon.

A device layer is formed on the top layer silicon of the base.

A through via penetrating through the device layer and the top layer silicon and extending into the bottom layer silicon is formed.

The through via is filled to form a conductive pillar.

Preprocessing is performed on the bottom layer silicon of the base to expose the conductive pillar to form a Through Silicon Via (TSV), in which the bottom layer silicon is configured to block a metal contaminant generated in the preprocessing.

According to a second aspect, the embodiments of the disclosure provide a semiconductor structure, including:

a base, in which the base includes top layer silicon and bottom layer silicon;

a device layer, in which the device layer is located on the top layer silicon of the base; and

a Through Silicon Via (TSV), in which the TSV is provided inside the base and penetrates through the base and the device layer.

### BRIEF DESCRIPTION OF THE DRAWINGS

FIG. 1A is a schematic cross-sectional view of a semiconductor structure after a Through Silicon Via (TSV) is formed according to an embodiment of the disclosure;

FIG. 1B is a schematic cross-sectional view of a semiconductor structure with a distal end of a TSV being exposed according to an embodiment of the disclosure;

FIG. 1C is a schematic cross-sectional view of a semiconductor structure after an oxide layer and a silicon nitride layer are formed according to an embodiment of the disclosure;

FIG. 1D is a schematic cross-sectional view of a semiconductor structure with a conductive layer in a TSV being exposed according to an embodiment of the disclosure;

FIG. 2 is an optional schematic flowchart of a method for manufacturing a semiconductor structure according to an embodiment of the disclosure;

FIG. 3A is a schematic cross-sectional view of a base according to an embodiment of the disclosure;

FIG. 3B is a schematic cross-sectional view of a semiconductor structure after a device layer is formed according to an embodiment of the disclosure;

FIG. 3C is a schematic cross-sectional view of a semiconductor structure after a through via is formed according to an embodiment of the disclosure;

FIG. 3D is a schematic cross-sectional view of a semiconductor structure after an isolation layer is formed in a through via according to an embodiment of the disclosure;

FIG. 3E is a schematic cross-sectional view of a semiconductor structure after a conductive pillar is formed according to an embodiment of the disclosure;

FIG. 3F is a schematic cross-sectional view of a semiconductor structure after an interconnect metal layer is formed according to an embodiment of the disclosure;

FIG. 3G is a schematic cross-sectional view of a semiconductor structure after a groove is formed according to an embodiment of the disclosure;

FIG. 3H is a schematic cross-sectional view of a semiconductor structure after a bump structure is formed according to an embodiment of the disclosure;

FIG. 3I is a schematic cross-sectional view of a semiconductor structure formed with a bump structure after the semiconductor structure formed with the bump structure is flipped according to an embodiment of the disclosure;

FIG. 3J is a schematic cross-sectional view of a semiconductor structure with a conductive pillar being exposed according to an embodiment of the disclosure;

FIG. 4A is a schematic cross-sectional view of another base according to an embodiment of the disclosure;

FIG. 4B is a schematic cross-sectional view of another semiconductor structure after a device layer is formed according to an embodiment of the disclosure;

FIG. 4C is a schematic cross-sectional view of another semiconductor structure after a through via is formed according to an embodiment of the disclosure;

FIG. 4D is a schematic cross-sectional view of another semiconductor structure after an isolation layer is formed in a through via according to an embodiment of the disclosure;

FIG. 4E is a schematic cross-sectional view of another semiconductor structure after a conductive pillar is formed according to an embodiment of the disclosure;

FIG. 4F is a schematic cross-sectional view of another semiconductor structure after an interconnect metal layer is formed according to an embodiment of the disclosure;

FIG. 4G is a schematic cross-sectional view of another semiconductor structure after a groove is formed according to an embodiment of the disclosure;

FIG. 4H is a schematic cross-sectional view of another semiconductor structure after a bump structure is formed according to an embodiment of the disclosure;

FIG. 4I is a schematic cross-sectional view of another semiconductor structure formed with a bump structure after the another semiconductor structure formed with the bump structure is flipped according to an embodiment of the disclosure;

FIG. 4J is a schematic cross-sectional view of another semiconductor structure with a conductive pillar being exposed according to an embodiment of the disclosure;

FIG. 5A is a schematic cross-sectional view of a through via located in bottom layer silicon and top layer silicon according to an embodiment of the disclosure; and

FIG. 5B is a schematic cross-sectional view of a through via located in bottom layer silicon, a buried oxide layer, and top layer silicon according to an embodiment of the disclosure.

### DETAILED DESCRIPTION

The following clearly and completely describes the technical solutions in embodiments of the disclosure with reference to the embodiments and the accompanying drawings of the disclosure. Apparently, the described embodiments are a part rather than all of the embodiments of the disclosure. All other embodiments obtained by persons of ordinary skill in the art based on the embodiments of the disclosure without creative efforts shall fall within the scope of protection of the disclosure.

In the description below, a large number of specific details are given to provide a more thorough understanding of the disclosure. However, it will be apparent to those skilled in the art that the disclosure can be implemented without one or more of these details. In other examples, in order to avoid confusion with the disclosure, some technical features that are well known in the art are not described. That is, all the features of actual embodiments are not described here, and functions and structures that are well known are not described in detail.

In the accompanying drawings, the dimensions of the layers, regions, and components, as well as their relative dimensions, may be exaggerated for clarity. The same reference numerals throughout the description indicate the same components.

It should be understood that when an element or layer is referred to as being “on”, “adjacent to”, “connected to”, or “coupled to” another element or layer, it can be directly on, adjacent to, connected to, or coupled to the another element or layer or an intervening element or layer may be present. In contrast, when an element is referred to as being “directly on”, “directly adjacent to”, “directly connected to”, or “directly coupled to” another element or layer, no intervening element or layer is present. It should be understood that, although the terms first, second, third etc. may be used to describe various elements, components, regions, layers, and/or sections, these elements, components, regions, layers, and/or sections should not be limited by these terms. These terms are only used to distinguish one element, component, region, layer, or section from another element, component, region, layer, or section. Therefore, a first element, component, region, layer, doping type or section discussed below could be referred to as a second element, component, region, layer, or section without departing from the teachings of the disclosure. When the second element, component, region, layer, or section is discussed, it does not indicate that the first element, component, region, layer, or section is necessarily present in the disclosure.

Spatially relative terms, such as “beneath”, “below”, “lower”, “under”, “above”, “upper”, and the like, may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements or features described as “below”, “beneath” or “under” other elements or features would then be oriented “above” the other elements or features. Therefore, the exemplary term “below” and “beneath” can encompass both orientations of above and below. The device may be otherwise oriented (rotated 90 degrees or at other orientations) and the spatially relative descriptors used herein are interpreted accordingly.

The terms used herein are intended to describe specific embodiments only and are not intended to constitute a limitation on the disclosure. As used herein, the singular forms “a,” “an”, and “the” are intended to include the plural forms as well, unless the context clearly indicates otherwise. It should also be understood that the terms “comprising” and/or “including”, when used in the specification, identify the presence of the features, integers, steps, operations, components and/or parts, but do not preclude the presence or addition of one or more other features, integers, steps, operations, components, parts and/or groups. As used herein, the term “and/or” in this specification includes any and all combinations of the associated listed items.

For a thorough understanding of the disclosure, detailed operations as well as detailed structures are proposed in the following description to facilitate the description of the technical embodiments of the disclosure. The preferred embodiments of the disclosure are described in detail below. However, the disclosure may have other embodiments in addition to these detailed descriptions.

As discussed above, a current method for forming a Through Silicon Via (TSV) mainly includes the following operations. A through via perpendicular to a silicon substrate is formed on a front surface of the silicon substrate. An insulating layer is formed on a side wall and a bottom of the through via. Chemical Mechanical Polishing (CMP) is performed on a rear surface of the silicon substrate until the through via filled with a conductive material is exposed, that is, a TSV is formed.

In a process of polishing the rear surface of the silicon substrate to expose the through via filled with the conductive material, the conductive material such as copper filled in the through via is very likely to contaminate the silicon substrate. Therefore, how to improve a Backside Via Reveal (BVR) technology for TSVs and reduce the contamination of a metal material to a silicon substrate is an urgent problem to be solved at present.

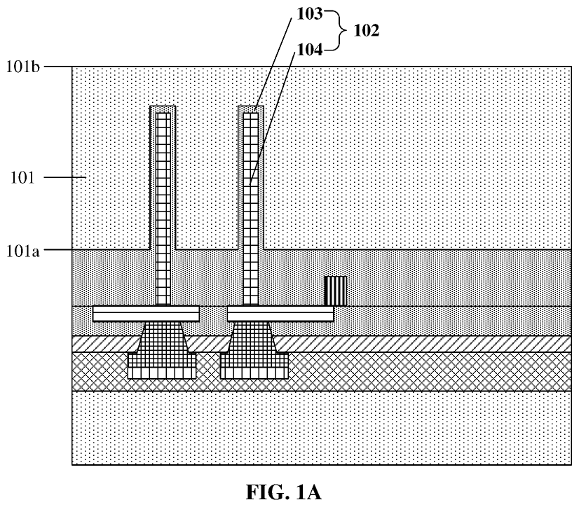

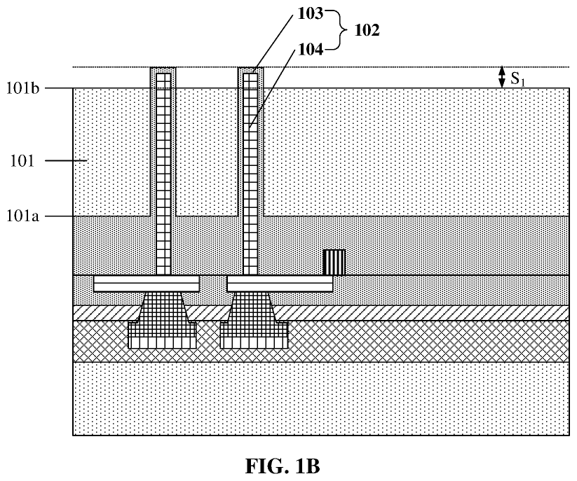

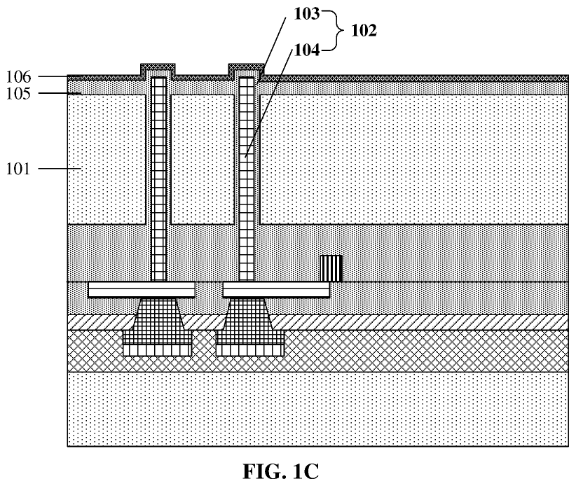

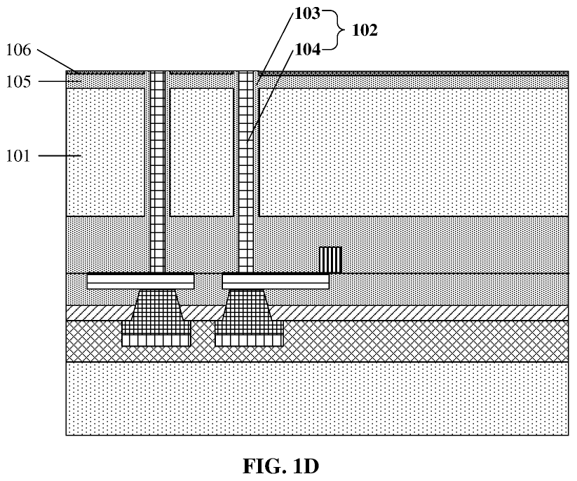

With reference to FIG. 1A, FIG. 1A is a schematic cross-sectional view of a semiconductor structure after a TSV is formed according to an embodiment of the disclosure. As shown in FIG. 1A, a TSV 102 extends from a first surface 101a of a silicon substrate 101 into the silicon substrate 101, and the TSV 102 does not penetrate through the silicon substrate 101. The direction in which the TSV 102 is formed through etching is perpendicular to the silicon substrate 101. After the TSV 102 is formed through etching, an isolation material is deposited on a side wall and a bottom in the TSV to form an isolation layer 103. Next, a conductive material is deposited in the TSV 102 to form a conductive layer 104. The silicon substrate 101 has a first surface 101a and a second surface 101b opposite to the first surface 101a. Specifically, the first surface may be a front surface of the silicon substrate, and the second surface may be a rear surface of the silicon substrate.

In some embodiments of the disclosure, the deposition of the isolation layer and the conductive layer in the TSV may be implemented by one or more deposition processes. The deposition process includes, but not limited to, Physical Vapor Deposition (PVD), Chemical Vapor Deposition (CVD), Atomic Layer Deposition (ALD) or any combination thereof.

In some embodiments of the disclosure, the isolation layer may include an oxide layer, for example, a silicon dioxide layer. The conductive layer may include a metal layer such as a copper layer.

With reference to FIG. 1B, FIG. 1B is a schematic cross-sectional view of a semiconductor structure with a distal end of a TSV being exposed according to an embodiment of the disclosure. Backside grinding is performed on the silicon substrate 101 from the second surface 101b of the silicon substrate in a direction perpendicular to the silicon substrate 101 to expose a distal end of the TSV, or the silicon substrate 101 is etched from the second surface 101b of the silicon substrate to expose a distal end of the TSV.

In a specific embodiment of the disclosure, backside grinding is performed on the silicon substrate, and a grinding thickness of the silicon substrate is about 20 μm. With reference to FIG. 1B, backside grinding is performed on the silicon substrate to expose the distal end of the TSV.

In a specific embodiment of the disclosure, dry etching may be performed on the silicon substrate from the second surface of the silicon substrate to expose the distal end of the TSV. The exposed distal end of the TSV may be exposed by an exposed distance of about 6.5 μm in the direction perpendicular to the silicon substrate. With reference to FIG. 1B, after the dry etching is performed on the silicon substrate, the distal end of the TSV is exposed. The exposed distal end of the TSV is exposed by an exposed distance S₁ in the direction perpendicular to the silicon substrate. S₁ may be about 6.5 μm.

FIG. 1C is a schematic cross-sectional view of a semiconductor structure after an oxide layer and a silicon nitride layer are formed according to an embodiment of the disclosure. As shown in FIG. 1C, an oxide layer 105 is deposited on the second surface of the silicon substrate 101. The oxide layer 105 covers the second surface of the silicon substrate 101 and the distal end of the TSV. A silicon nitride layer 106 is deposited on the oxide layer 105. The silicon nitride layer 106 completely covers the oxide layer 105.

In some embodiments of the disclosure, the formation of the oxide layer on the second surface of the silicon substrate and the formation of the silicon nitride layer on the oxide layer may be implemented by one or more deposition processes. The deposition process includes, but not limited to, PVD, CVD, ALD or any combination thereof.

In a specific embodiment of the disclosure, the thickness of the formed oxide layer covering the second surface of the silicon substrate and the distal end of the TSV is about 1.85 μm.

In a specific embodiment of the disclosure, the thickness of the formed silicon nitride layer covering the oxide layer is about 0.3 μm.

With reference to FIG. 1D, FIG. 1D is a schematic cross-sectional view of a semiconductor structure with a conductive layer in a TSV being exposed according to an embodiment of the disclosure. As shown in FIG. 1D, the isolation layer 103 at the distal end of the TSV is removed from the second surface of the silicon substrate 101 by CMP to expose the conductive layer 104 at the distal end of the TSV.

In the foregoing technical solution, the oxide layer and the silicon nitride layer are successively formed at the distal end of the TSV, so that the contamination of the material of the conductive layer to the silicon substrate can be effectively mitigated in a subsequent process of using the CMP to expose the conductive layer at the distal end of the TSV. The oxide layer and the silicon nitride layer covering the distal end of the TSV may serve as protection layers to isolate a material contaminant such as a metal contaminant of the conductive layer generated in the polishing on the surface of the silicon nitride layer or the oxide layer.

However, in the foregoing BVR technical solution for TSVs, an additional process operation needs to be added after the TSV is formed, to form the oxide layer and the silicon nitride layer as protection layers. Therefore, the technical solution increases the process difficulty of the BVR technology for TSVs, increases the process costs, and makes the process complex.

In view of this, the embodiments of the disclosure provide a method for manufacturing a semiconductor structure. The top layer silicon and the bottom layer silicon are disposed, and after the conductive pillar penetrating through the top layer silicon and extending into the bottom layer silicon is formed, preprocessing is performed on the bottom layer silicon to expose the conductive pillar, so that the process difficulty is reduced and the process costs are reduced, and moreover the bottom layer silicon can be configured to block a metal contaminant generated in the preprocessing.

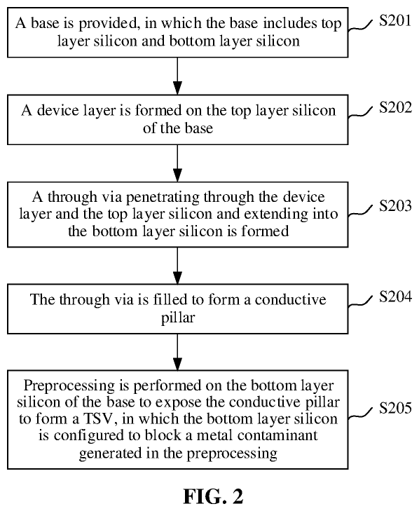

FIG. 2 is an optional schematic flowchart of a method for manufacturing a semiconductor structure according to an embodiment of the disclosure. As shown in FIG. 2, the embodiments of the disclosure provide a method for manufacturing a semiconductor structure, and the method includes the following operations.

At S201, a base is provided, in which the base includes top layer silicon and bottom layer silicon.

At S202, a device layer is formed on the top layer silicon of the base.

At S203, a through via penetrating through the device layer and the top layer silicon and extending into the bottom layer silicon is formed.

At S204, the through via is filled to form a conductive pillar.

At S205, preprocessing is performed on the bottom layer silicon of the base to expose the conductive pillar to form a TSV, in which the bottom layer silicon is configured to block a metal contaminant generated in the preprocessing.

Next, a method for manufacturing a semiconductor structure provided in an embodiment of the disclosure is further described below in detail.

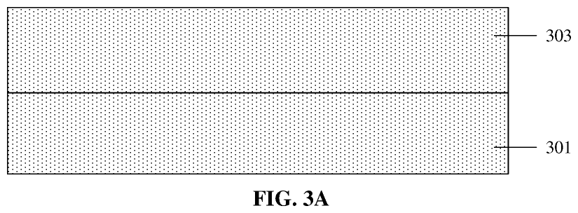

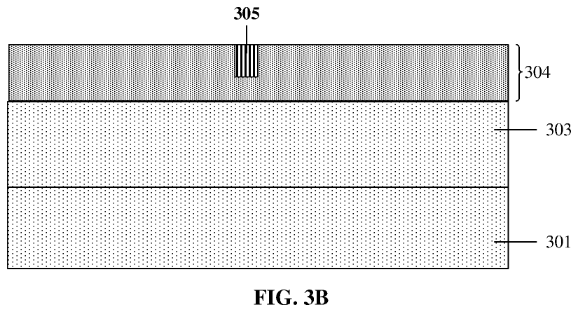

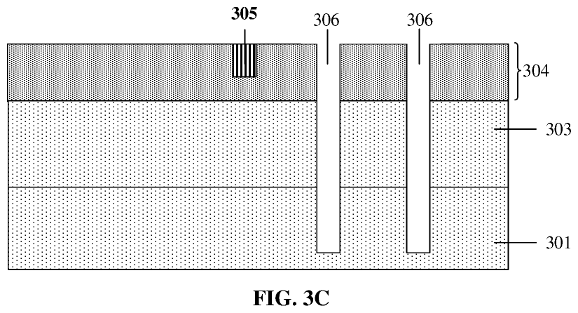

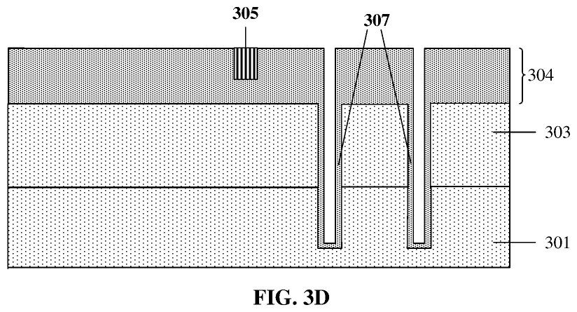

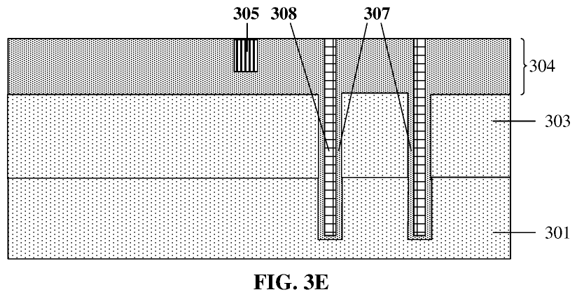

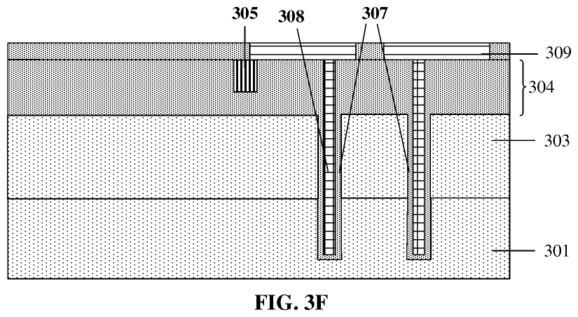

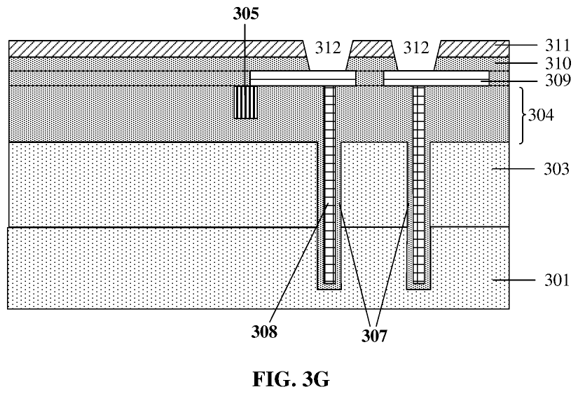

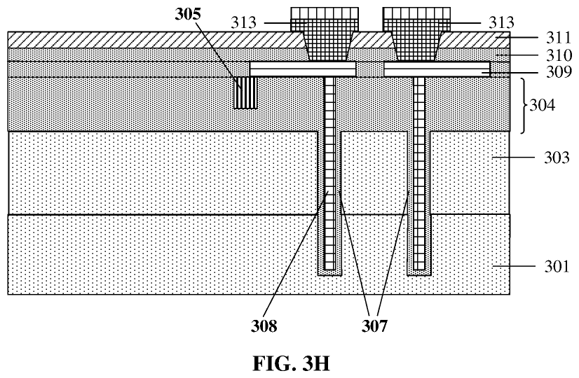

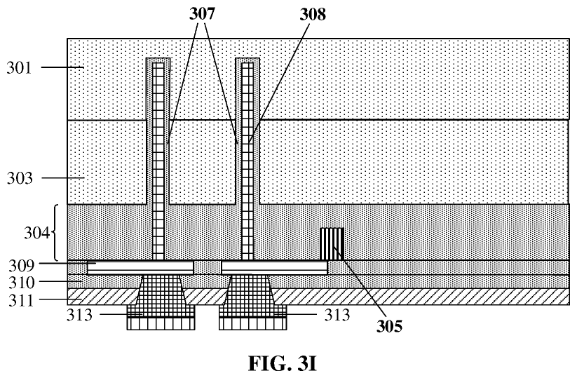

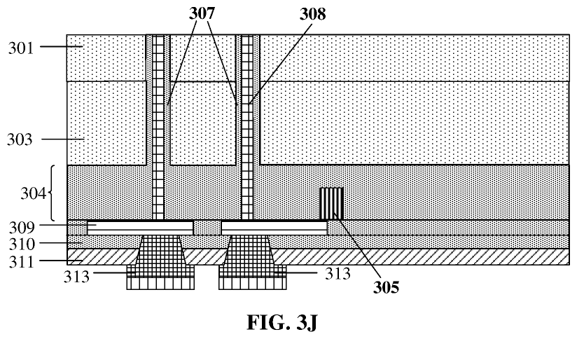

With reference to FIG. 3A, FIG. 3A is a schematic cross-sectional view of a base according to an embodiment of the disclosure. As shown in FIG. 3A, the base includes bottom layer silicon 301 and top layer silicon 303.

In some embodiments of the disclosure, a thickness of the top layer silicon is greater than a thickness of the bottom layer silicon.

In a process of preprocessing the bottom layer silicon to expose the conductive pillar, the bottom layer silicon is configured to block a metal contaminant generated in the preprocessing. After preprocessing is performed on the bottom layer silicon to expose the conductive pillar, the bottom layer silicon may serve as a protection layer to isolate the metal contaminant generated in the preprocessing from the top layer silicon. Therefore, the thickness of the bottom layer silicon may be less than the thickness of the top layer silicon. Subsequently, the bottom layer silicon may be removed.

In some embodiments of the disclosure, a grain size of the bottom layer silicon is less than a grain size of the top layer silicon.

As discussed above, the bottom layer silicon is configured to block the metal contaminant generated in the preprocessing. Therefore, the grain arrangement of the bottom layer silicon will be more dense, since the grain size of the bottom layer silicon is less than the grain size of the top layer silicon. In this way, the bottom layer silicon has a better effect of blocking the metal contaminant, so that the metal contaminant can be effectively prevented from being embedded in the bottom layer silicon.

With reference to FIG. 3B, FIG. 3B is a schematic cross-sectional view of a semiconductor structure after a device layer is formed according to an embodiment of the disclosure. As shown in FIG. 3B, a device layer 304 is formed on the top layer silicon 303. The device layer 304 includes a semiconductor device 305 arranged in the device layer 304. It needs to be noted that the specific structure of the device layer is not schematically shown in the embodiments of the disclosure, and it is only schematically shown that a semiconductor device is arranged in the device layer. In addition, a ratio of the thickness of the device layer to the thickness of another material layer should not be construed as a limitation on the thickness of the device layer in the disclosure.

In some embodiments of the disclosure, the device layer includes a transistor device and a capacitor device. The device layer includes a dielectric layer and a transistor device and a capacitor device formed in the dielectric layer.

The semiconductor device formed in the device layer may include a transistor device and a capacitor device. The transistor device may include one or more Metal-Oxide-Semiconductor Field-Effect Transistors (MOSFET). The transistor may include a planar transistor, a non-planar transistor or a combination thereof. The planar transistor may include a Bipolar Junction Transistor (BJT), a Heterojunction Bipolar Transistor (HBT) or a High Electron Mobility Transistor (HEMT). The non-planar transistor may include a Fin Field-Effect Transistor (FinFET) (for example, a double gate transistor or a triple gate transistor) and a surrounding gate or gate-all-around transistor (for example, a nanoribbon or nanowire transistor).

A process of forming a semiconductor device in the embodiments of the disclosure involves a Front End of Line (FEOL) process in a semiconductor manufacturing process.

With reference to FIG. 3C, FIG. 3C is a schematic cross-sectional view of a semiconductor structure after a through via is formed according to an embodiment of the disclosure. As shown in FIG. 3C, a through via 306 penetrating through the device layer 304 and the top layer silicon 303 and extending into the bottom layer silicon 301 is formed.

In the embodiments of the disclosure, the device layer, the top layer silicon, and the bottom layer silicon may be etched by wet etching, dry etching or a combination thereof to form the through via.

In the embodiments of the disclosure, a patterned photoresist layer may be formed on the device layer. The device layer, the top layer silicon, and the bottom layer silicon are etched successively by using the patterned photoresist layer to form the through via penetrating through the device layer and the top layer silicon and extending into the bottom layer silicon. After the through via is formed, the photoresist layer may be removed. That is, photoresist strip (PR strip) is performed.

In some embodiments of the disclosure, the operation that the through via penetrating through the device layer and the top layer silicon and extending into the bottom layer silicon is formed includes: a diameter of a part of the through via located in the bottom layer silicon is greater than or equal to a diameter of a part of the through via located in the top layer silicon.

A process parameter for etching may be changed, for example, an etching time may be extended, so that the diameter of the part of the through via located in the bottom layer silicon is greater than or equal to the diameter of the part of the through via located in the top layer silicon. In this way, after the through via is filled to form the conductive pillar, a dimension of a part of the conductive pillar located in the bottom layer silicon is greater than or equal to a dimension of a part of the conductive pillar located in the top layer silicon. After preprocessing is performed on the bottom layer silicon to expose the conductive pillar, the part of the conductive pillar located in the bottom layer silicon is configured to implement an electrical connection. Therefore, the dimension of the part of the conductive pillar located in the bottom layer silicon is increased, so that a contact area of an electrical connection between the conductive pillar and another semiconductor device can be increased, thereby improving the effect of the electrical connection.

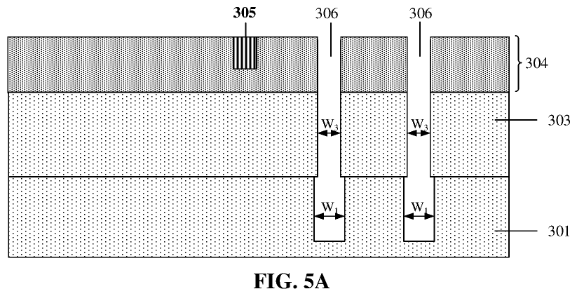

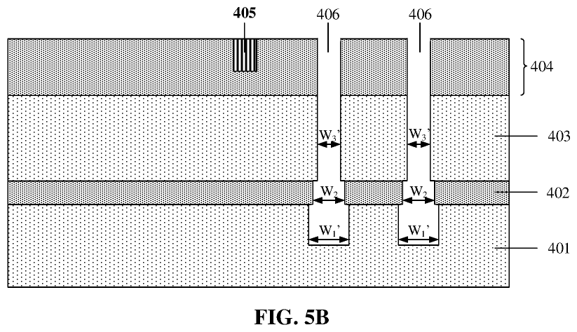

With reference to FIG. 3C, the diameter of the part of the through via located in the bottom layer silicon is equal to the diameter of the part of the through via located in the top layer silicon as shown in FIG. 3C. FIG. 5A is a schematic cross-sectional view of a through via located in bottom layer silicon and top layer silicon according to an embodiment of the disclosure. The diameter W₁ of the part of the through via located in the bottom layer silicon is greater than the diameter W₃ of the part of the through via located in the top layer silicon as shown in FIG. 5A. In this way, after the through via is filled to form the conductive pillar, a dimension of a part of the conductive pillar located in the bottom layer silicon is greater than or equal to a dimension of a part of the conductive pillar located in the top layer silicon.

With reference to FIG. 3D, FIG. 3D is a schematic cross-sectional view of a semiconductor structure after an isolation layer is formed in a through via according to an embodiment of the disclosure. As shown in FIG. 3D, an isolation layer 307 is deposited on a side wall and a bottom of the through via.

In the embodiments of the disclosure, the deposition of the isolation layer in the through via may be implemented by one or more deposition processes. The deposition process includes, but not limited to, PVD, CVD, ALD or any combination thereof. In the embodiments of the disclosure, the isolation layer may be deposited in the through via by using a liner deposition source.

FIG. 3E is a schematic cross-sectional view of a semiconductor structure after a conductive pillar is formed according to an embodiment of the disclosure. As shown in FIG. 3E, the through via is filled with a conductive material to form a conductive pillar 308.

In the embodiments of the disclosure, the conductive pillar may be deposited in the through via by a method including, but not limited to, vacuum evaporation, sputtering plating, and ion plating. After the conductive pillar is formed, the excess conductive material may be removed by CMP, so that an upper surface of the conductive pillar is flush with an upper surface of the device layer.

In the embodiments of the disclosure, the conductive material for forming the conductive pillar may include, but not limited to, a metal material. In an embodiment of the disclosure, the material for forming the conductive pillar is, for example, copper.

With reference to FIG. 3F, FIG. 3F is a schematic cross-sectional view of a semiconductor structure after an interconnect metal layer is formed according to an embodiment of the disclosure. As shown in FIG. 3F, an interconnect layer (not shown in the figure) is formed on the device layer 304. The interconnect layer is electrically connected to the conductive pillar. The interconnect layer includes an interconnect via and an interconnect metal layer. The interconnect metal layer includes a top metal layer 309. The interconnect layer is electrically connected to the semiconductor device 305, and the top metal layer 309 is electrically connected to the conductive pillar.

In some embodiments of the disclosure, a dielectric layer is deposited on the device layer, and a patterned photoresist layer is formed on the dielectric layer. The dielectric layer is etched by using the patterned photoresist layer to form the pattern of the top metal layer, and a material is filled to form the top metal layer 309. The material of the dielectric layer may be silicon dioxide.

In other embodiments of the disclosure, a metal material layer is deposited on the device layer, and a patterned photoresist layer is formed on the metal material layer. The metal material layer is etched by using the patterned photoresist layer to form the top metal layer.

With reference to FIG. 3G, FIG. 3G is a schematic cross-sectional view of a semiconductor structure after a groove is formed according to an embodiment of the disclosure. As shown in FIG. 3G, an insulating layer 310 and a passivation layer 311 covering the interconnect layer are formed. The passivation layer 311 and the insulating layer 310 are etched to form a groove 312 exposing the top metal layer 309.

In some embodiments of the disclosure, the material for forming the insulating layer may be silicon dioxide.

In some embodiments of the disclosure, the material for forming the passivation layer (PAS layer) by deposition may include, but not limited to, silicon nitride.

With reference to FIG. 3H, FIG. 3H is a schematic cross-sectional view of a semiconductor structure after a bump structure is formed according to an embodiment of the disclosure. As shown in FIG. 3H, the passivation layer 311 covers an upper surface of the insulating layer 310. A conductive material is deposited in the groove to form a bump structure 313. The bump structure 313 is electrically connected to the top metal layer 309.

In some embodiments of the disclosure, the conductive material for forming the bump structure by deposition may include, but not limited to, a metal material. For example, the conductive material for forming the bump structure may be copper.

With reference to FIG. 3I, FIG. 3I is a schematic cross-sectional view of a semiconductor structure formed with a bump structure after the semiconductor structure formed with the bump structure is flipped according to an embodiment of the disclosure. As shown in FIG. 3I, a wafer formed with the bump structure is flipped (wafer flip).

With reference to FIG. 3J, FIG. 3J is a schematic cross-sectional view of a semiconductor structure with a conductive pillar being exposed according to an embodiment of the disclosure. As shown in FIG. 3J, preprocessing is performed on the bottom layer silicon 301, to remove the isolation layer 307 at a distal end of the conductive pillar 308 to expose the conductive pillar 308. Certainly, in a process of performing preprocessing to remove the isolation layer, a part of the material of the conductive pillar is inevitably removed. The preprocessing may include, but not limited to, CMP.

After preprocessing is performed on the bottom layer silicon to expose the conductive pillar, the bottom layer silicon may serve as a protection layer to isolate the metal contaminant generated in the preprocessing from the top layer silicon.

In the method for manufacturing a semiconductor structure provided in the embodiments of the disclosure, the top layer silicon and the bottom layer silicon are disposed, and after the conductive pillar penetrating through the top layer silicon and extending into the bottom layer silicon is formed, preprocessing is performed on the bottom layer silicon to expose the conductive pillar. It is not necessary to add an additional process operation, and the bottom layer silicon may be configured to block a metal contaminant generated in the preprocessing, thereby effectively preventing the metal contaminant from contaminating the top layer silicon. The embodiments of the disclosure provide a method for manufacturing a semiconductor structure, which can reduce the process difficulty and the process costs, and can further reduce the contamination of the metal contaminant to the silicon substrate (top layer silicon).

Next, a method for manufacturing a semiconductor structure provided in another embodiment of the disclosure is further described below in detail.

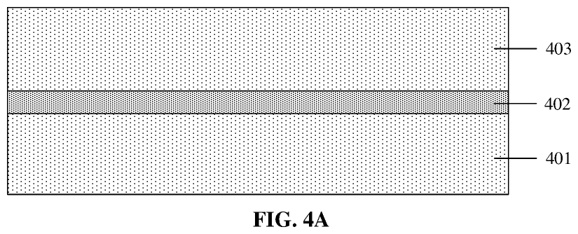

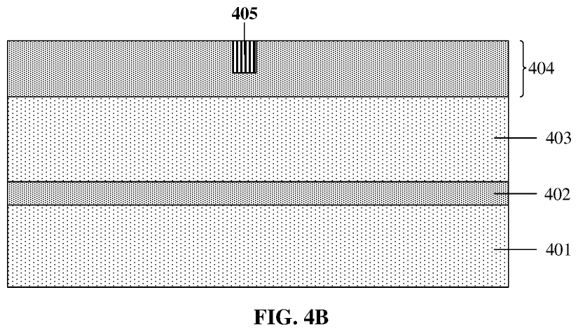

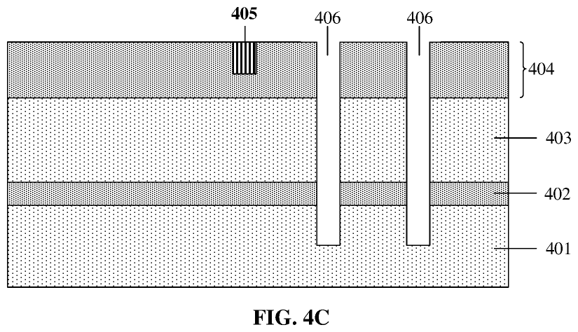

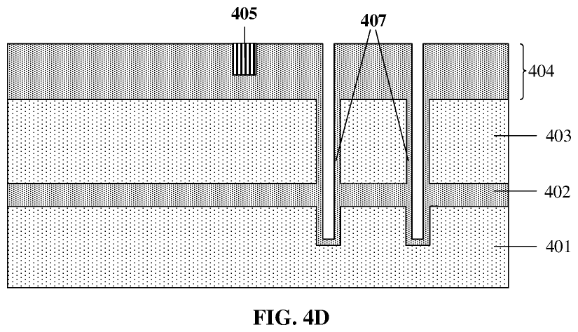

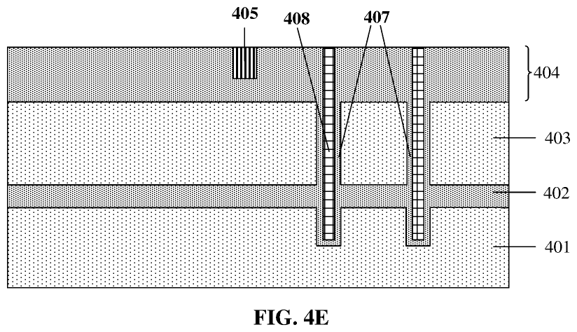

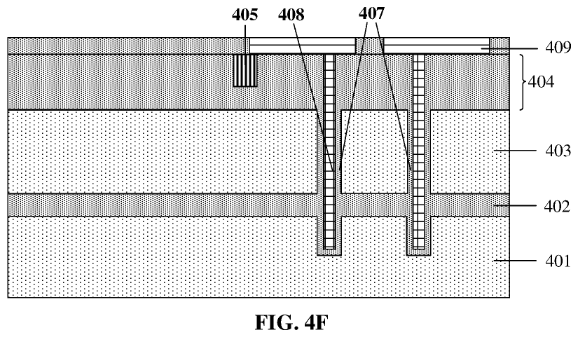

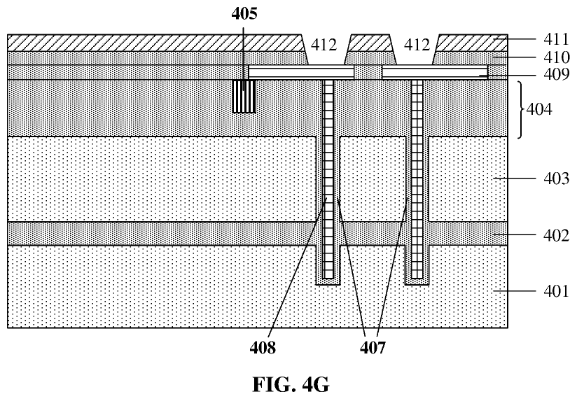

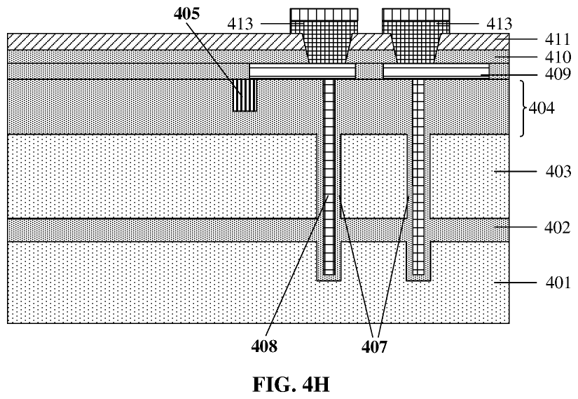

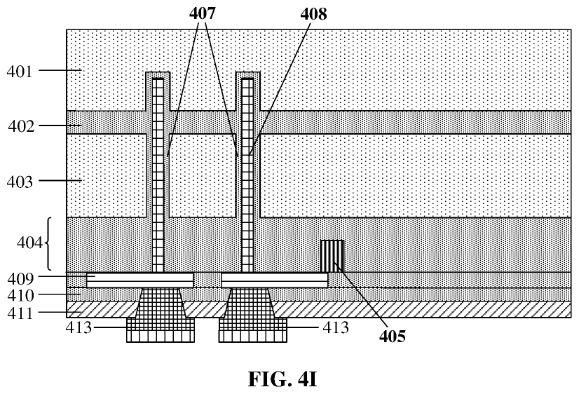

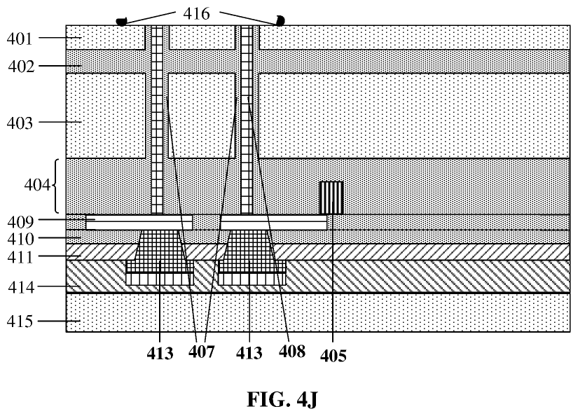

With reference to FIG. 4A, FIG. 4A is a schematic cross-sectional view of another base according to an embodiment of the disclosure. As shown in FIG. 4A, the base includes bottom layer silicon 401, top layer silicon 403, and a buried oxide layer 402 located between the bottom layer silicon 401 and the top layer silicon 403.

The base may include Silicon-On-Insulator (SOI). That is, one oxide material layer is disposed between two layers of silicon material. The use of the SOI in the semiconductor device provides various advantages, for example, including: reducing a parasitic capacitance, and increasing a running speed; reducing power consumption; eliminating a latch-up effect; inhibiting pulse current interference in a base, and reducing the occurrence of soft errors; and implementing compatibility with an existing silicon process, and reducing working procedures by 13% to 20%.

Specifically, parasitic capacitances between source-drain diffusion areas of an N-Metal-Oxide-Semiconductor (NMOS) and a P-Metal-Oxide-Semiconductor (PMOS) and the substrate change linearly with the change of a doping concentration in the substrate. As the dimension of a semiconductor device keeps decreasing, to mitigate a short channel effect, the doping concentration in the substrate needs to be appropriately increased, a source-drain junction capacitance increases accordingly, and a parasitic capacitance between a source-drain junction and a channel cut-off region increases accordingly. The increase in the parasitic capacitance reduces the running speed of the circuit and increases the power consumption of the circuit. In the SOI, the parasitic capacitance between the source-drain junction and the substrate is a buried insulator capacitance. The capacitance is directly proportional to the dielectric constant of the buried oxide layer. The dielectric constant of the silicon dioxide of the buried oxide layer is only one third of the dielectric constant of silicon. In addition, as the dimension of a semiconductor device keeps decreasing, the thickness of the buried oxide layer does not need to be proportionally reduced, and the parasitic capacitance does not increase. The use of the SOI in the semiconductor device can reduce a parasitic capacitance, increase a running speed, and reduce power consumption.

Specifically, in the SOI, the devices are all surrounded by the oxide layer and are completely isolated from the surrounding devices, thereby eliminating a latch-up effect. Therefore, when the SOI is used in the semiconductor device, because there is no current channel to the substrate, a vertical path for the latch-up effect is cut off, so that the latch-up effect can be eliminated.

Specifically, when device structures with the same performance are implemented on the SOI and the bulk silicon material, the SOI device does not require additional process operations of manufacturing an isolation structure. Therefore, the use of the SOI in the semiconductor device can simplify a manufacturing process.

In a process of performing preprocessing on the bottom layer silicon to expose the conductive pillar, the bottom layer silicon and the buried oxide layer are configured to block a metal contaminant generated in the preprocessing. After preprocessing is performed on the bottom layer silicon to expose the conductive pillar, the bottom layer silicon and the buried oxide layer may serve as protection layers to isolate the metal contaminant generated in the preprocessing from the top layer silicon.

Therefore, in the method for manufacturing a semiconductor structure provided in the embodiments of the disclosure, SOI can be directly used as a substrate of the semiconductor structure, so that the difficulty for the BVR technology is reduced, the process of the BVR technology is simplified, the costs of the BVR technology are reduced, and furthermore the contamination of the conductive material to the substrate is reduced.

With reference to FIG. 4B, FIG. 4B is a schematic cross-sectional view of a semiconductor structure after a device layer is formed according to another embodiment of the disclosure. As shown in FIG. 4B, a device layer 404 is formed on the top layer silicon 403. The device layer 404 includes a semiconductor device 405 arranged in the device layer 404. It needs to be noted that the specific structure of the device layer is not schematically shown in the embodiments of the disclosure, and it is only schematically shown that a semiconductor device is arranged in the device layer. In addition, a ratio of the thickness of the device layer to the thickness of another material layer should not be construed as a limitation on the thickness of the device layer in the disclosure.

In some embodiments of the disclosure, the device layer includes a transistor device and a capacitor device. The device layer includes a dielectric layer and a transistor device and a capacitor device formed in the dielectric layer.

With reference to FIG. 4C, FIG. 4C is a schematic cross-sectional view of another semiconductor structure after a through via is formed according to an embodiment of the disclosure. As shown in FIG. 4C, a through via 406 penetrating through the device layer 404, the top layer silicon 403, and the buried oxide layer 402 and extending into the bottom layer silicon 401 is formed.

In some embodiments of the disclosure, the operation that the through via successively penetrating through the device layer, the top layer silicon, and the buried oxide layer and extending into the bottom layer silicon is formed includes: a diameter of a part of the through via located in the buried oxide layer is greater than or equal to a diameter of a part of the through via located in the top layer silicon; and a diameter of a part of the through via located in the bottom layer silicon is greater than or equal to the diameter of the part of the through via located in the buried oxide layer.

A process parameter for etching may be changed, for example, an etching time may be extended, so that the diameter of the part of the through via located in the buried oxide layer is greater than or equal to the diameter of the part of the through via located in the top layer silicon and the diameter of the part of the through via located in the bottom layer silicon is greater than or equal to the diameter of the part of the through via located in the buried oxide layer. In this way, after the through via is filled to form the conductive pillar, a dimension of a part of the conductive pillar located in the bottom layer silicon is greater than or equal to a dimension of a part of the conductive pillar located in the top layer silicon. After preprocessing is performed on the bottom layer silicon to expose the conductive pillar, the part of the conductive pillar located in the bottom layer silicon is configured to implement an electrical connection. Therefore, the dimension of the part of the conductive pillar located in the bottom layer silicon is increased, so that a contact area of an electrical connection between the conductive pillar and another semiconductor device can be increased, thereby improving the effect of the electrical connection.

With reference to FIG. 4C, the diameter of the part of the through via located in the buried oxide layer is equal to the diameter of the part of the through via located in the top layer silicon, and the diameter of the part of the through via located in the bottom layer silicon is equal to the diameter of the part of the through via located in the buried oxide layer, as shown in FIG. 4C. With reference to FIG. 5B, FIG. 5B is a schematic cross-sectional view of a through via located in bottom layer silicon, a buried oxide layer, and top layer silicon according to an embodiment of the disclosure. The diameter W₂ of the part of the through via located in the buried oxide layer is greater than the diameter W₃′ of the part of the through via located in the top layer silicon, and the diameter W₁′ of the part of the through via located in the bottom layer silicon is greater than the diameter W₂ of the part of the through via located in the buried oxide layer, as shown in FIG. 5B. In this way, after the through via is filled to form the conductive pillar, a dimension of a part of the conductive pillar located in the bottom layer silicon is greater than a dimension of a part of the conductive pillar located in the top layer silicon.

With reference to FIG. 4D, FIG. 4D is a schematic cross-sectional view of another semiconductor structure after an isolation layer is formed in a through via according to an embodiment of the disclosure. As shown in FIG. 4D, an isolation layer 407 is deposited on a side wall and a bottom of the through via.

With reference to FIG. 4E, FIG. 4E is a schematic cross-sectional view of another semiconductor structure after a conductive pillar is formed according to an embodiment of the disclosure. As shown in FIG. 4E, the through via is filled with a conductive material to form a conductive pillar 408.

With reference to FIG. 4F, FIG. 4F is a schematic cross-sectional view of another semiconductor structure after an interconnect metal layer is formed according to an embodiment of the disclosure. As shown in FIG. 4F, an interconnect layer (not shown in the figure) is formed on the device layer 404. The interconnect layer is electrically connected to the conductive pillar. The interconnect layer includes an interconnect via and an interconnect metal layer. The interconnect metal layer includes a top metal layer 409. The interconnect layer is electrically connected to the semiconductor device 405, and the top metal layer 409 is electrically connected to the conductive pillar.

With reference to FIG. 4G, FIG. 4G is a schematic cross-sectional view of another semiconductor structure after a groove is formed according to an embodiment of the disclosure. As shown in FIG. 4G, an insulating layer 410 and a passivation layer 411 covering the interconnect layer are formed. The passivation layer 411 and the insulating layer 410 are etched to form a groove 412 exposing the top metal layer 409.

With reference to FIG. 4H, FIG. 4H is a schematic cross-sectional view of another semiconductor structure after a bump structure is formed according to an embodiment of the disclosure. As shown in FIG. 4H, the passivation layer 411 covers an upper surface of the insulating layer 410. A conductive material is deposited in the groove to form a bump structure 413. The bump structure 413 is electrically connected to the top metal layer 409.

With reference to FIG. 4I, FIG. 4I is a schematic cross-sectional view of another semiconductor structure formed with a bump structure after the another semiconductor structure formed with the bump structure is flipped according to an embodiment of the disclosure. As shown in FIG. 4I, a wafer formed with the bump structure 413 is flipped.

With reference to FIG. 4J, FIG. 4J is a schematic cross-sectional view of another semiconductor structure with a conductive pillar being exposed according to an embodiment of the disclosure. As shown in FIG. 4J, a bonding layer 414 covering the bump structure 413 is formed on the passivation layer 411, the semiconductor structure is bonded to a carrier 415 by the bonding layer 414, and preprocessing is performed on the bottom layer silicon 401 to expose the conductive pillar 408. Certainly, in a process of performing preprocessing to remove the isolation layer, a part of the material of the conductive pillar is inevitably removed. The preprocessing may include, but not limited to, CMP. The carrier is only configured to support the semiconductor structure to facilitate subsequent preprocessing of the bottom layer silicon.

With reference to FIG. 4J, after preprocessing is performed on the bottom layer silicon 401 to expose the conductive pillar 408, the bottom layer silicon 401 and the buried oxide layer 402 may serve as protection layers to isolate the metal contaminant 416 generated in the preprocessing from the top layer silicon 403.

Therefore, in the method for manufacturing a semiconductor structure provided in the embodiments of the disclosure, SOI can be directly used as a substrate of the semiconductor structure, so that the difficulty for the BVR technology is reduced, the process of the BVR technology is simplified, the costs of the BVR technology are reduced, and furthermore the contamination of a conductive material to the substrate can be reduced.

With reference to FIG. 3J, the embodiments of the disclosure further provide a semiconductor structure, including:

a base, in which the base includes top layer silicon 303 and bottom layer silicon 301;

a device layer 304, in which the device layer 304 is located on the top layer silicon 303 of the base; and

a TSV, in which the TSV is provided inside the base and penetrates through the base and the device layer 304.

After the conductive pillar 308 is formed, preprocessing is performed on the bottom layer silicon 301 of the base to expose the conductive pillar 308 to form the TSV.

The preprocessing is performed on the bottom layer silicon to expose the conductive pillar. In this way, the bottom layer silicon can be configured to block a metal material generated in the preprocessing from contaminating the top layer silicon (that is, a silicon substrate). It is not necessary to arrange an additional protection layer to block a metal material from contaminating a silicon substrate, so that process operations of the BVR technology for TSVs are simplified.

In some embodiments of the disclosure, a grain size of the bottom layer silicon is less than a grain size of the top layer silicon.

The grain size of the bottom layer silicon is less than the grain size of the top layer silicon, so that the grain arrangement of the bottom layer silicon will be more dense. In this way, the bottom layer silicon has a better effect of blocking the metal contaminant, so that the metal contaminant can be effectively prevented from being embedded in the bottom layer silicon, thereby protecting the top layer silicon from contamination by the metal material.

In some embodiments of the disclosure, the base further includes a buried oxide layer located between the bottom layer silicon and the top layer silicon.

The bottom layer silicon and the buried oxide layer are configured to block a metal contaminant generated in the preprocessing. After preprocessing is performed on the bottom layer silicon to expose the conductive pillar, the bottom layer silicon and the buried oxide layer may serve as protection layers to isolate the metal contaminant generated in the preprocessing from the top layer silicon, thereby protecting the top layer silicon from contamination by the metal material.

In some embodiments of the disclosure, the device layer includes a transistor device and a capacitor device.

In some embodiments of the disclosure, the semiconductor structure further includes an interconnect layer located on the device layer and electrically connected to the TSV. The interconnect layer includes an interconnect through via and an interconnect metal layer.

In some embodiments of the disclosure, the semiconductor structure further includes a passivation layer and a bump structure formed in the passivation layer. The passivation layer is located on the interconnect layer, and the bump structure is electrically connected to the interconnect layer.

In some embodiments of the disclosure, a conductive material is filled in the TSV.

In some embodiments of the disclosure, the TSV is provided inside the base and penetrates through the base and the device layer in the following way:

a diameter of a part of the TSV located in the buried oxide layer is greater than or equal to a diameter of a part of the TSV located in the top layer silicon; and

a diameter of a part of the TSV located in the bottom layer silicon is greater than or equal to the diameter of the part of the TSV located in the buried oxide layer.

The diameter of the part of the TSV located in the buried oxide layer is greater than or equal to the diameter of the part of the TSV located in the top layer silicon, and the diameter of the part of the TSV located in the bottom layer silicon is greater than or equal to the diameter of the part of the TSV located in the buried oxide layer. Therefore, the dimension of the part of the TSV located in the bottom layer silicon is increased, so that a contact area of an electrical connection between the conductive pillar and another semiconductor device can be increased, thereby improving the effect of the electrical connection.

Embodiments of the disclosure provide a semiconductor structure and a method for manufacturing a semiconductor structure. The method includes: a base is provided, in which the base includes top layer silicon and bottom layer silicon; a device layer is formed on the top layer silicon of the base; a through via penetrating through the device layer and the top layer silicon and extending into the bottom layer silicon is formed; the through via is filled to form a conductive pillar to form a TSV; and preprocessing is performed on the bottom layer silicon of the base to expose the conductive pillar, in which the bottom layer silicon is configured to block a metal contaminant generated in the preprocessing. In the method for manufacturing a semiconductor structure provided in the embodiments of the disclosure, top layer silicon and bottom layer silicon are disposed. After a conductive pillar penetrating through the top layer silicon and extending into the bottom layer silicon is formed, preprocessing is performed on the bottom layer silicon to expose the conductive pillar. In this way, the bottom layer silicon can be configured to block a metal material generated in the preprocessing from contaminating the top layer silicon (that is, a silicon substrate). It is not necessary to arrange an additional protection layer to block a metal material from contaminating a silicon substrate, so that process operations of the BVR technology for TSVs are simplified.

It should be understood that references throughout the specification to “one embodiment” or “an embodiment” mean that particular features, structures or characteristics associated with the embodiment are included in at least one embodiment of the disclosure. Therefore, the words “in one embodiment” or “in an embodiment” appearing throughout the specification do not necessarily refer to the same embodiment. In addition, these particular features, structures, or characteristics may be combined in any appropriate manner in one or more embodiments. It should be understood that in the various embodiments of the disclosure, the sequence numbers of the above processes do not imply the order of execution, and the order of execution of the processes shall be determined by their functions and intrinsic logic, and shall not constitute any limitation to the processes implemented in the embodiments of the disclosure. The foregoing sequence numbers embodiments of the disclosure are merely for the convenience of description, and do not imply the preference among the embodiments.

The above is only preferred embodiments of the disclosure and is not intended to limit the scope of the patent of the disclosure. Any equivalent structure transformation using the content of the specification of the disclosure and the accompanying drawings under the inventive concept of the disclosure or any direct or indirect application in other related technical fields, falls within the scope of protection of the patent of the disclosure.

1. A method for manufacturing a semiconductor structure, comprising:
providing a base, wherein the base comprises top layer silicon and bottom layer silicon;
forming a device layer on the top layer silicon of the base;
forming a through via penetrating through the device layer and the top layer silicon and extending into the bottom layer silicon;
filling the through via to form a conductive pillar; and
performing preprocessing on the bottom layer silicon of the base to expose the conductive pillar to form a Through Silicon Via (TSV), wherein the bottom layer silicon is configured to block a metal contaminant generated in the preprocessing.

2. The method for manufacturing according to claim 1, wherein the preprocessing comprises polishing.

3. The method for manufacturing according to claim 1, wherein a grain size of the bottom layer silicon is less than a grain size of the top layer silicon.

4. The method for manufacturing according to claim 1, wherein a thickness of the top layer silicon is greater than a thickness of the bottom layer silicon.

5. The method for manufacturing according to claim 1, wherein the base further comprises a buried oxide layer located between the bottom layer silicon and the top layer silicon, wherein forming the through via penetrating through the device layer and the top layer silicon and extending into the bottom layer silicon comprises:
forming the through via successively penetrating through the device layer, the top layer silicon, and the buried oxide layer and extending into the bottom layer silicon.

6. The method for manufacturing according to claim 5, wherein
a diameter of a part of the through via located in the buried oxide layer is greater than or equal to a diameter of a part of the through via located in the top layer silicon; and
a diameter of a part of the through via located in the bottom layer silicon is greater than or equal to the diameter of the part of the through via located in the buried oxide layer.

7. The method for manufacturing according to claim 1, wherein the device layer comprises a transistor device and a capacitor device.

8. The method for manufacturing according to claim 1, wherein before performing preprocessing on the bottom layer silicon of the base, the method further comprises:
forming an interconnect layer on the device layer, wherein the interconnect layer is electrically connected to the conductive pillar,
wherein the interconnect layer comprises an interconnect through via and an interconnect metal layer.

9. The method for manufacturing according to claim 8, wherein before performing preprocessing on the bottom layer silicon of the base, the method further comprises:
forming a passivation layer covering the interconnect layer, and etching the passivation layer to form a groove exposing the interconnect layer; and
forming a bump structure in the groove, wherein the bump structure is electrically connected to the interconnect layer.

10. A semiconductor structure, comprising:
a base, wherein the base comprises top layer silicon and bottom layer silicon;
a device layer, wherein the device layer is located on the top layer silicon of the base; and
a Through Silicon Via (TSV), wherein the TSV is provided inside the base and penetrates through the base and the device layer.

11. The semiconductor structure according to claim 10, wherein a grain size of the bottom layer silicon is less than a grain size of the top layer silicon.

12. The semiconductor structure according to claim 10, wherein
the base further comprises a buried oxide layer located between the bottom layer silicon and the top layer silicon.

13. The semiconductor structure according to claim 10, wherein the device layer comprises a transistor device and a capacitor device.

14. The semiconductor structure according to claim 10, further comprising:
an interconnect layer, wherein the interconnect layer is located on the device layer, and is electrically connected to the TSV,
wherein the interconnect layer comprises an interconnect through via and an interconnect metal layer.

15. The semiconductor structure according to claim 14, further comprising:
a passivation layer and a bump structure formed in the passivation layer, wherein the passivation layer is located on the interconnect layer,
wherein the bump structure is electrically connected to the interconnect layer.

16. The semiconductor structure according to claim 10, wherein the TSV is filled with a conductive material.

17. The semiconductor structure according to claim 12, wherein
a diameter of a part of the TSV located in the buried oxide layer is greater than or equal to a diameter of a part of the TSV located in the top layer silicon; and
a diameter of a part of the TSV located in the bottom layer silicon is greater than or equal to the diameter of the part of the TSV located in the buried oxide layer.
